(19) United States
(12) Patent Application Publication
(10) Pub. No.: US 2009/0065820 A1
(43) Pub. Date: Mar. 12, 2009

(54) Method and structure for simultaneously fabricating selective film and spacer

(76) Inventor: Lu-Yang Kao, Ping-Tung City (TW)

Correspondence Address: NORTH AMERICA INTELLECTUAL PROPERTY CORPORATION, P.O. BOX 506, MERRIFIELD, VA, 22116, US

(21) Appl. No.: 11/851,373

(22) Filed: Sep. 6, 2007

(51) Int. Cl. H01L 27/146; H01L 31/18

(52) U.S. Cl. 257/292; 438/72; 257/E27.133; 257/E31.128

(57) ABSTRACT

The present invention provides a method for simultaneously fabricating a selective film and a spacer. First, a semiconductor substrate is provided and a first device area and a second device area are defined on the semiconductor substrate. At least a gate is formed on the semiconductor substrate in the second device area. Subsequently, at least a dielectric material is formed on the semiconductor substrate and the dielectric material covers the first device area and the second device area. A patterned mask is then formed on a portion of the dielectric material. Subsequently, an etching process is carried out to remove the dielectric material not covered by the patterned mask, thereby a selective film is formed in the first device area and simultaneously spacers are formed on the sidewalls of the gate in the second device area. Finally, the patterned mask is removed.

### BACKGROUND OF THE INVENTION

1. Field of the Invention

The present invention relates to a method for simultaneously fabricating a selective film and a spacer, and more particularly, to a method for simultaneously fabricating a selective film and a spacer of an image sensor.

2. Description of the Prior Art

Today's image sensors in common usage are divided into two main categories: charge couple device (CCD) sensors and complementary metal oxide semiconductor image sensors (CMOS image sensors; CIS). The application of CMOS image sensors has been widely adopted for several reasons as described hereinafter. Primarily, CMOS image sensors have advantages such as offering a lower operating voltage, reduced power consumption, and the ability of random access. Additionally, CMOS image sensors are currently capable of integration with the semiconductor fabricating process.

Additionally, as the development of optical storage technology, the storage medium with the advantages of ease to use, low cost, portability, and high capacity, has progressed from the conventional optical disc (CD) with a data capacity of 650 to 800 MB to the digital versatile disc (DVD) with a data capacity of about 4.7 GB, and further to the most popular blue-ray disc (BD) with a data capacity of over 25 GB. Compared with conventional DVDs and CDs which use red and infrared lasers at 650 nm and 780 nm to read and write data respectively, the blue-ray disc system uses a blue-violet laser operating at a wavelength 405 nm to read and write data, which explains the reason substantially more data can be stored on a blue-ray disc. It would thus be highly desirable to provide a photo detector integration circuit (PDIC) with a corresponding image sensor capable of efficiently sensing the blue laser reflected from the blue-ray disc to read and write data.

Please refer to FIG. 1 to FIG. 3, which are cross-sectional diagrams illustrating a method of fabricating a CMOS image sensor capable of sensing the blue laser in accordance with the prior art. FIG. 1 to FIG. 3 merely show a light sensor area and a device area. As shown in FIG. 1, a P type semiconductor substrate 100 is provided. A light sensor area 102 and a device area 104 are defined on the P type semiconductor substrate 100. The light sensor area 102 further comprises at least an N+diffusion region within the P type semiconductor substrate 100. Therefore, a photodiode 108 made of the PN junction is formed in the light sensor area 102. A gate structure 110 is formed on the P type semiconductor substrate 100 in the device area 104. The gate structure 110 further comprises a gate dielectric layer 112, a gate conductive layer 114 positioned on the gate dielectric layer 112, a cap layer positioned on the gate conductive layer 114, and spacers 118 positioned on the sidewalls of the gate conductive layer 114. Subsequently, a multiple deposition process is carried out to form a silicon nitride material 120, a silicon oxide material 122, and a polysilicon material 124 on the semiconductor substrate 100.

As shown in FIG. 2, a patterned mask 126 such as a photoresist is coated on the semiconductor substrate 100 to cover each material above the photodiode 108. A series of selective etching processes are carried out. For example, a dry etching is first carried out to remove the polysilicon material 124 not covered by the patterned mask 126; a buffer oxide etchant (BOE) is used to remove the silicon oxide material 122 not covered by the patterned mask 126; finally a hot phosphorous etchant is used to remove the silicon nitride material 130 not covered by the patterned mask 126. Therefore, a stacked layer 134 composed of a silicon nitride layer 128 positioned on the semiconductor substrate 100, a silicon oxide layer 130 positioned on the silicon nitride layer 128, and a polysilicon layer 132 positioned on the silicon oxide layer 130 is formed above the photodiode 108. The silicon nitride layer 128 in the stacked layer 134 acts as a selective film with the function of anti-reflection in an image sensor.

As shown in FIG. 3, corresponding dopants are implanted into the semiconductor substrate 100 to form light doped regions or source/drain regions, etc (not shown). Conductive regions 136 such as conductive dopant or metal silicide, etc, are formed within the semiconductor substrate 100. According to the different circuit designs, demanded inter-layer dielectric (ILD) layers 138_1, 138_2 . . . 138_n, conductive plugs 140_1, 140_2 . . . 140_n, and metal layers 142_1, 142_2 . . . 142_n are then formed on the semiconductor substrate 100. Among which the conductive regions 136 are connected with the corresponding metal layers 142_1 through the conductive plug 140_1; each metal layers 142_1, 142_2 . . . 142_n are also connected with each other through the corresponding conductive plugs 140_2 . . . 140_n and therefore further connected to the outside circuits or other devices.

Subsequently, a patterned mask (not shown) is coated on the semiconductor substrate 100 to define the predetermined position of forming a deep trench 144 on the photodiode 108 in the light sensor area 102. At least an etching process is carried out to remove the inter-layer dielectric layers 138_1, 138_2 . . . 138_n, the polysilicon layer 132, and the silicon oxide layer 130 not covered by the patterned mask until the silicon nitride layer 128 is exposed. Finally, the patterned mask is removed.

According to the prior art described above, the inter-layer dielectric layers have a total thickness of about 60000 angstroms. If those inter-layer dielectric layers are not removed, when the photodiodes in the different regions on the same wafer receive the same incident light, the problem of producing different photoelectric responses will occur caused by the thickness non-uniformity. Furthermore, the strength of the incident light is reduced by the excessive thickness of the inter-layer dielectric layers. Therefore, forming a deep trench to expose the photodiode is needed.

Additionally, the purpose of forming a silicon nitride layer with a higher refractivity on the photodiode is to eliminate the angle deviations caused from different wavelength ranges. Using the silicon nitride layer can also improve the efficiency of photoelectric conversions of the blue laser. Therefore, a CMOS image can have a better ability of sensing the blue laser by fabricating a silicon nitride layer on the photodiode and exposing the silicon nitride layer by a deep trench structure.

However, the above technique still suffers the following disadvantages. First, because the gate structure is formed in the device area before performing the entire deposition process of each material, the thickness of each material adjacent to the gate structure in the area with higher pattern density is thicker. As shown in FIG. 4, which is a scanning electron microscopy (SEM) picture of a device area in a conventional CMOS image sensor after depositing each material. The silicon nitride material, silicon oxide material, and polysilicon material are designated as A′, B′, and C′ respectively. Accordingly, if the etching time of defining the selective film is not enough, there will be some residues remaining between the gate structures as shown in FIG. 5. FIG. 5 is a scanning electron microscopy picture of a device area in a conventional CMOS image sensor after defining a selective film. There is silicon nitride residue (SiN residue) remaining between the gate structures. The remaining residues will hinder the conductive ions from implanting into the semiconductor substrate and thus cause the relative devices to fail.

On the contrary, if the etching time is prolonged to overcome the thickness variation caused by the patterned density or by the deposition process, the variation of the profiles of the spacers is increased. Therefore, the stability of electronic performance of the relative devices in different regions of the same wafer or in different wafers of the same lot is decreased.

Besides, as shown in FIG. 2, the silicon nitride layer 128 is formed by using hot phosphorous acid to remove the silicon nitride material 120 not covered by the patterned mask 126. However, the spacers 118 are often damaged by the phosphorous acid. Thus the electronic performance of the corresponding devices is affected.

Accordingly, the applicant provide a method of simultaneously fabricating a selective film and a spacer in the light sensor area and in the device area respectively to improve the shortages from the prior art, and further increase the stability of the electronic performance of the devices.

### SUMMARY OF THE INVENTION

The present invention relates to a method for simultaneously fabricating a selective film and a spacer, and more particularly, to a method for simultaneously fabricating a selective film and a spacer of an image sensor.

According to the claims, the present provides a method for simultaneously fabricating a selective film and a spacer. The method comprises providing a semiconductor substrate, the semiconductor substrate defining a first device area and a second device area, and the second device area comprising at least a gate; forming at least a dielectric material on the semiconductor substrate, the dielectric material covering the gate; forming a patterned mask to cover a portion of the dielectric material in the first device area; performing an etching process to remove the dielectric material not covered by the patterned mask to form the selective film in first device area and the spacers on the sidewalls of the gate in the second device area simultaneously; and removing the patterned mask.

According to the claims, the present invention further provides an image sensor structure fabricated according to the method described above. The image sensor structure comprises a semiconductor substrate, a first device area and a second device area defined on the semiconductor substrate; at least a selective film positioned on the surface of the semiconductor substrate in the first device area; and at least a gate structure positioned on the surface of the semiconductor substrate in the second device area, wherein the spacer of the gate structure and the selective film comprise the same constituent material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are cross-sectional diagrams, illustrating a method of fabricating a CMOS image sensor capable of sensing blue laser in accordance with the prior art.

FIG. 4 shows a scanning electron microscopy picture of a device area in a conventional CMOS image sensor after depositing each material.

FIG. 5 shows a scanning electron microscopy picture of a device area in a conventional CMOS image sensor after defining a selective film.

FIG. 6 to FIG. 9 are cross-sectional diagrams, illustrating a method of fabricating a CMOS image sensor according to the first preferred embodiment of the present invention.

FIG. 10 to FIG. 13 are cross-sectional diagrams, illustrating a method of fabricating a CMOS image sensor according to the second preferred embodiment of the present invention.

FIG. 14 to FIG. 15 are cross-sectional diagrams, illustrating a method of simultaneously fabricating a selective film and a spacer according to the third preferred embodiment of the present invention.

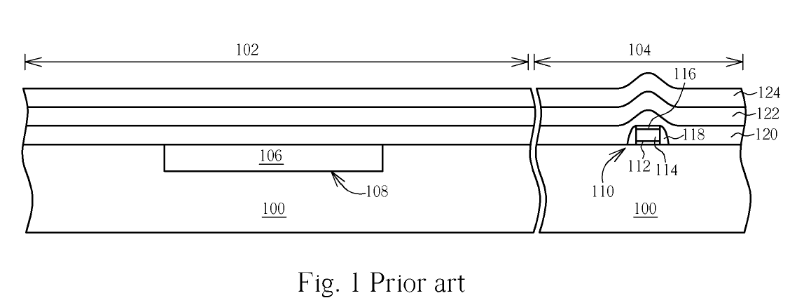

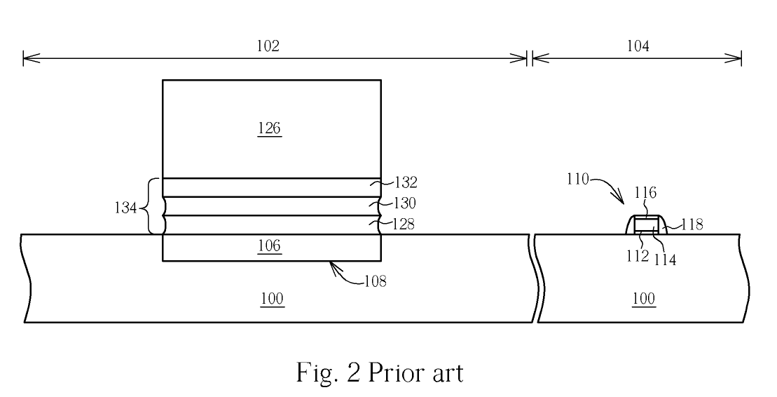

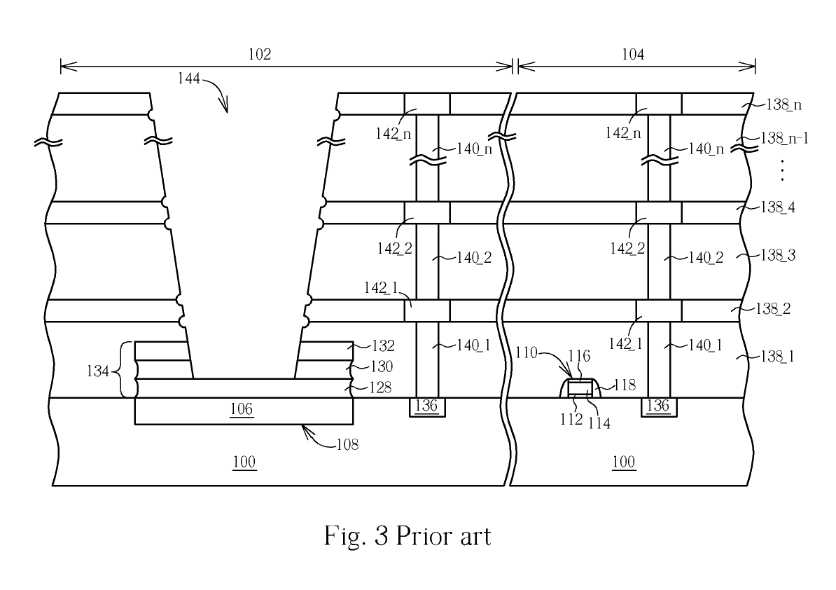

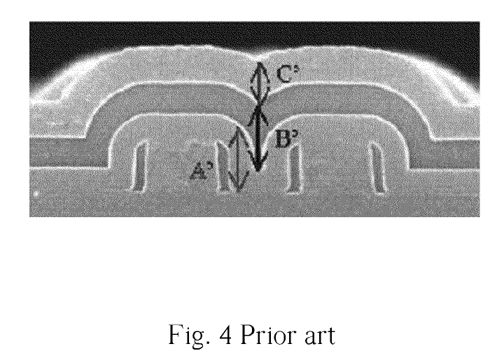

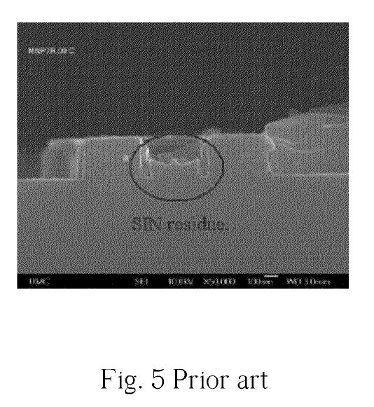

### DETAILED DESCRIPTION

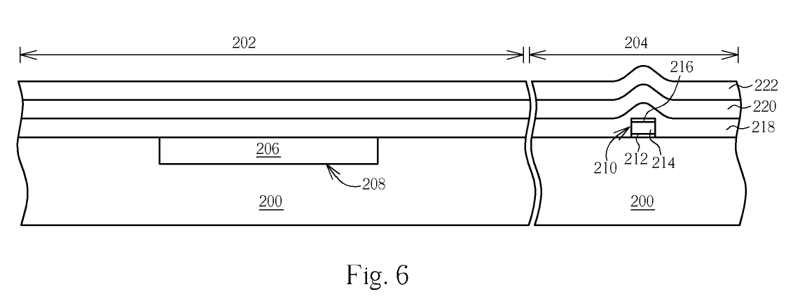

Please refer to FIG. 6 to FIG. 9, which are cross-sectional diagrams illustrating a method of fabricating a CMOS image sensor according to the first preferred embodiment of the present invention. For highlighting the characteristic of the present invention and for clarity of the illustration, FIG. 6 to FIG. 9 merely show a light sensor area and a device area. As shown in FIG. 6, a semiconductor substrate 200 is provided such as a silicon substrate or a silicon-on-insulator (SOI) substrate, etc. The semiconductor substrate 200 comprises at least a light sensor area 202 and at least a device area 204.

Subsequently, at least a light sensor such as a photodiode 208 is formed in the light sensor area 202. For example, when conductive ions with the opposite conductivity to the semiconductor substrate 200 are implanted into the semiconductor substrate 200 to form an ion diffusion region 206, therefore, a photodiode 208 composed of the opposite conductivity junction is formed in the semiconductor substrate 200. According to the first preferred embodiment of the present invention, the semiconductor substrate 200 is a P type semiconductor substrate and the ion diffusion region 206 is an N+type diffusion region; thus the photodiode 208 composed of the PN junction is formed within the semiconductor substrate 200 in the light sensor area 202. Additionally, an epitaxial layer (not shown) may be formed in the semiconductor substrate 200, and the ion diffusion region 206 may be formed in this epitaxial layer.

A gate 210 is then formed on the semiconductor substrate 200 in the device area 204. The gate 210 comprises a gate dielectric layer 212, a gate conductive layer 214 positioned on the gate dielectric layer 212, and a cap layer 216 positioned on the gate conductive layer 214. Generally, the gate dielectric layer 212 comprises isolating materials such as silicon oxide components or silicon nitride components, etc; the gate conductive layer 214 comprises conductive materials such as polysilicon or metal silicide, etc; and the cap layer 216 comprises dielectric materials such as silicon nitride, etc. It should be noticed that the cap layer 216 is not limited to be formed on the gate conductive layer 214 at this time. It depends on the materials of the metal silicide, which is used to lower the sheet resistance, formed on the gate structure, source/drain region in the following fabrication processes. For example, if the metal silicide is composed of tungsten silicide, the cap layer 216 is formed on the gate conductive layer 214 at the time as shown in FIG. 6. However, if the metal silicide is composed of cobalt silicide, or titanium silicide, or tantalum silicide, etc, formed by an self-aligned silicidation (salicide), then the cap layer 216 will not be formed on the gate conductive layer 214 at the time as shown in FIG. 6. Those skilled in the art will readily observe that numerous modifications and alterations of the method may be made while retaining the teachings of the invention.

Thereafter, a multiple deposition process is carried out to form a dielectric material 218, a first sacrifice material 220, and a second sacrifice material 222 on the semiconductor substrate 200. According to the first preferred embodiment of the present invention, the dielectric material 218 comprises isolating materials with anti-reflection property or with higher refractivity such as silicon oxide components, silicon nitride components, etc: a silicon nitride material deposited by a low-pressure chemical vapor deposition (LPCVD), for instance. The first sacrifice material 220 comprises any material with a higher etching selectivity to the dielectric material 218 such as a tetra-ethyl-ortho-silicate (TEOS) silicon oxide material deposited by using the TEOS as a precursor. The second sacrifice material 222 comprises any material with a higher etching selectivity to the first sacrifice material 220 such as polysilicon material, etc. The dielectric material 218, the first sacrifice layer 220, and the second sacrifice layer 222 have a thickness of about 100 to 5000 angstroms respectively.

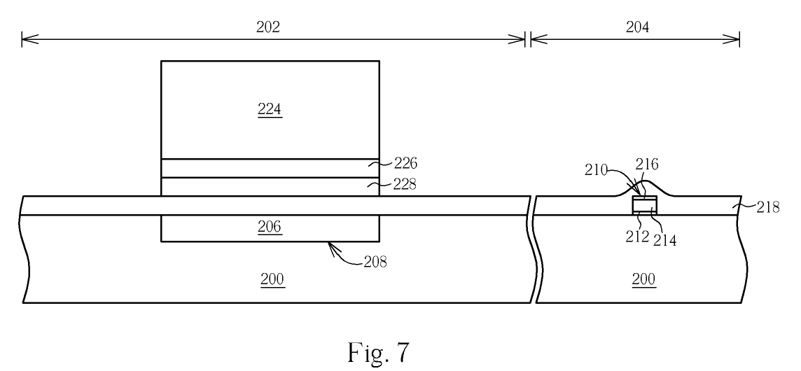

As shown in FIG. 7, a patterned mask 224 such as a photoresist is coated on the semiconductor substrate 200 to define a predetermined position of a selective film on the photodiode 208. At least an etching process is then carried out to remove the second sacrifice material 222 and the first sacrifice material 220; therefore a first sacrifice layer 228 is formed on the dielectric material 218 and a second sacrifice layer 226 is formed on the first sacrifice layer 228. According to the first preferred embodiment of the present invention, the etching process of removing the second sacrifice material 222 may be an anisotropic etching such as a sputtering etching process, a plasma etching process, or a reactive ion etching process (RIE process), etc. The etching process of removing the first sacrifice material 220 may be an isotropic wet etching process: wet etching process using buffered oxide as an etchant, for instance.

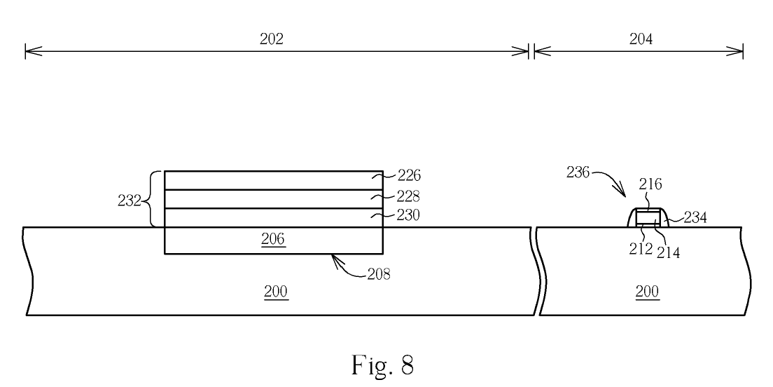

As shown in FIG. 8, another etching process is carried out to remove the dielectric material 218 not covered by the patterned mask 224. Therefore, a dielectric layer 230 is formed on the photodiode 208 in the light sensor area 202, and at the same time, spacers 234 is formed on the sidewalls of the gate 210 in the device area 204. The patterned mask 224 is then removed. Accordingly, a stacked layer 232 comprising the dielectric layer 230, the first sacrifice layer 228, and the second sacrifice layer 226 is defined on the photodiode 208 in the light sensor area 202. Among the stacked layer 232, the dielectric layer 230 acts as a selective film with the function of anti-reflection in an image sensor. It should be noticed that when the etching process is carried out to remove the dielectric material 218 on the photodiode 208 in the light sensor area 202, the etching process is also performed to etch back the dielectric material 218 in the device area 204. Thereby, the spacers 234 are formed on the sidewalls of the gate 210 in the device area 204 and the gate structure 236 is consequently formed in the device area 204. Therefore, both the spacers 234 and the dielectric layer 230 formed in device area 204 and the light sensor area 202 respectively comprise the same dielectric material formed simultaneously. According to the first preferred embodiment of the present invention, the etching process for removing the dielectric material 218 may be an anisotropic etching such as a sputtering etching process, a plasma etching process, or a reactive ion etching process (RIE process), etc, or an isotropic etching such as a wet etching using any etchant capable of removing the dielectric material 218. But the effect of the anisotropic etching is better.

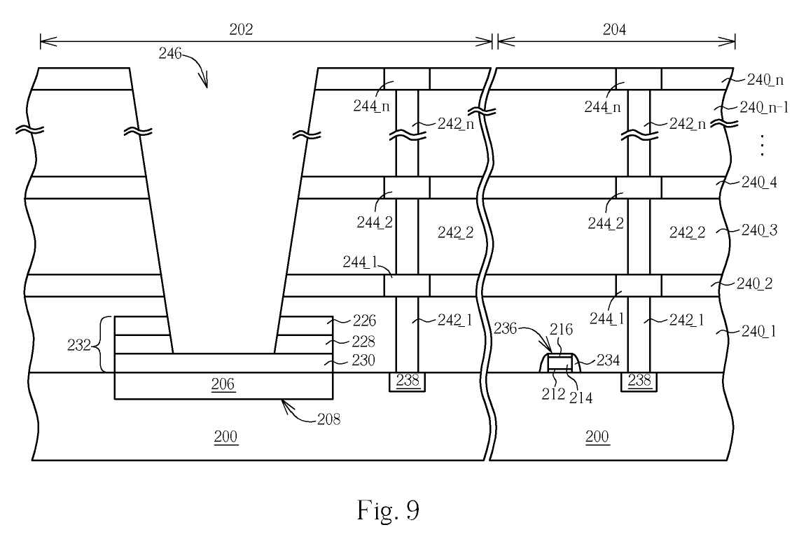

As shown in FIG. 9, corresponding dopants are implanted into the semiconductor substrate 200 to form light doped regions or source/drain regions, etc (not shown). Conductive regions 238 such as conductive dopant or metal silicide, etc, are formed within the semiconductor substrate 200. According to the different circuit designs, demanded inter-layer dielectric (ILD) layers 240_1, 240_2 . . . 240_n, conductive plugs 242_1, 242_2 . . . 242_n, and metal layers 244_1, 244_2 . . . 244_n are then formed on the semiconductor substrate 200. Among which the conductive regions 238 are connected with the corresponding metal layers 244_1 through the conductive plug 242_1; metal layers 244_1, 244_2 . . . 244_n are also connected with each other through the corresponding conductive plugs 242_2 . . . 242_n and therefore further connected to the outside circuits or other devices.

Subsequently, a patterned mask (not shown) is coated on the semiconductor substrate 200 to define the predetermined position of forming a deep trench 246 on the photodiode 208 in the light sensor area 202. At least an etching process is carried out to remove the inter-layer dielectric layers 240_1, 240_2 . . . 240_n, the second sacrifice layer 226, and the first sacrifice layer 228 until the dielectric layer 230 in the stacked layer 232 is exposed. Finally, the patterned mask is removed. It should be noticed that the dielectric layer 230 can be used as a selective film with the function of anti-reflection in an image sensor, and it can also be used as an etching stop layer in the aforesaid etching process for deep trench 246.

Because the inter-layer dielectric layers 240_1, 240_2 . . . 240_n have a higher etching selectivity to the second sacrifice layer 226, the second sacrifice layer 226 has a higher etching selectivity to the first sacrifice layer 228, and the first sacrifice layer 228 has a higher etching selectivity to the dielectric layer 230; therefore, each layer interferes in sensing of incident light on the photodiode 208, i.e. the inter-layer dielectric layers 240_1, 240_2 . . . 240_n, the second sacrifice layer 226, and the first sacrifice layer 228, can be removed completely but can also protect the dielectric layer 230 which improves the efficiency of photoelectric conversions from damaging.

It should be noticed that the sacrifice layers (i.e. first sacrifice layer 228 and the second sacrifice layer 226) on the dielectric layer 230 are not limited to the aforesaid double layer. Any single layer or multiple layers with an appropriate etching selectivity to the dielectric layer 230, namely with the property of being removed completely and protecting the dielectric layer 230 from damaging during the etching process of forming the deep trench 246, may be used as well.

According to the first preferred embodiment of the present invention, the etching process of removing the inter-layer dielectric layers 240_1, 240_2 . . . 240_n may be an anisotropic etching such as a sputtering etching process, a plasma etching process, or a reactive ion etching process, etc. The etching process of removing the second sacrifice layer 226 may be the same method as the etching process of removing the second sacrifice material 222 described in FIG. 7. The etching process of removing the first sacrifice layer 228 may be the same method as the etching process of removing the first sacrifice material 220 as described in FIG. 7.

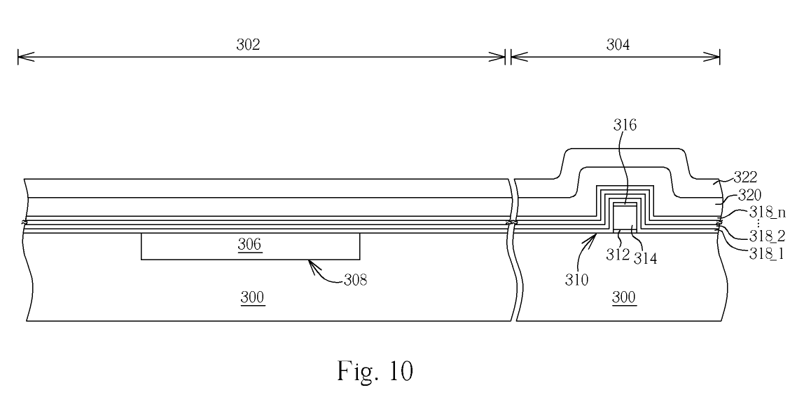

Please refer to FIG. 10 to FIG. 13, which are cross-sectional diagrams illustrating a method of fabricating a CMOS image sensor according to the second preferred embodiment of the present invention. For highlighting the characteristic of the present invention and for clarity of the illustration, FIG. 10 to FIG. 13 merely show a light sensor area and a device area. As shown in FIG. 10, a semiconductor substrate 300 is provided such as a silicon substrate or a silicon-on-insulator (SOI) substrate, etc. The semiconductor substrate 300 comprises at least a light sensor area 302 and at least a device area 304.

Subsequently, at least a light sensor such as a photodiode 308 is formed in the light sensor area 302. For example, when conductive ions with the opposite conductivity to the semiconductor substrate 300 are implanted into the semiconductor substrate 300 to form an ion diffusion region 306, therefore, a photodiode 308 composed of the opposite conductivity junction is formed in the semiconductor substrate 300. According to the second preferred embodiment of the present invention, the semiconductor substrate 300 is a P type semiconductor substrate and the ion diffusion region 306 is an N+ type diffusion region; thus the photodiode 308 composed of the PN junction is formed within the semiconductor substrate 300 in the light sensor area 302. Additionally, an epitaxial layer (not shown) may be formed in the semiconductor substrate 300, and the ion diffusion region 306 may be formed in this epitaxial layer.

A gate 310 is then formed on the semiconductor substrate 300 in the device area 304. The gate 310 comprises a gate dielectric layer 312, a gate conductive layer 314 positioned on the gate dielectric layer 312, and a cap layer 316 positioned on the gate conductive layer 314. Generally, the gate dielectric layer 312 comprises isolating materials such as silicon oxide components or silicon nitride components, etc; the gate conductive layer 314 comprises conductive materials such as polysilicon or metal silicide, etc; and the cap layer 316 comprises dielectric materials such as silicon nitride, etc. Thereafter, a multiple deposition process is carried out to form in order at least two dielectric materials 318_1, 318_2 . . . 318_n, a first sacrifice material 320, and a second sacrifice material 322 on the semiconductor substrate 300.

It should be noticed that the cap layer 316 is not limited to be formed on the gate conductive layer 314 at this time. It depends on the materials of the metal silicide, which is used to lower the sheet resistance, formed on the gate structure, source/drain region in the following fabrication processes. For example, if the metal silicide is composed of tungsten silicide, the cap layer 316 is formed on the gate conductive layer 314 at the time shown in FIG. 10. However, if the metal silicide is composed of cobalt silicide, or titanium silicide, or tantalum silicide, etc, formed by an self-aligned silicidation (salicide), then the cap layer 316 will not be formed on the gate conductive layer 314 at the time shown in FIG. 10. Those skilled in the art will readily observe that numerous modifications and alterations of the method may be made while retaining the teachings of the invention.

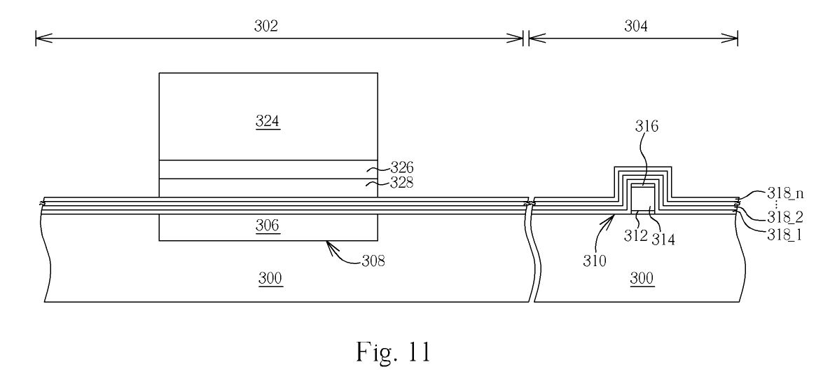

As shown in FIG. 11, a patterned mask 324 such as a photoresist is coated on the semiconductor substrate 300 to cover each material above the photodiode 308. At least an etching process is then carried out to remove the second sacrifice material 322 and the first sacrifice material 320; therefore a first sacrifice layer 228 is formed on the multiple dielectric materials 318_1, 318_2 . . . 318_n and a second sacrifice layer 326 is formed on the first sacrifice layer 328.

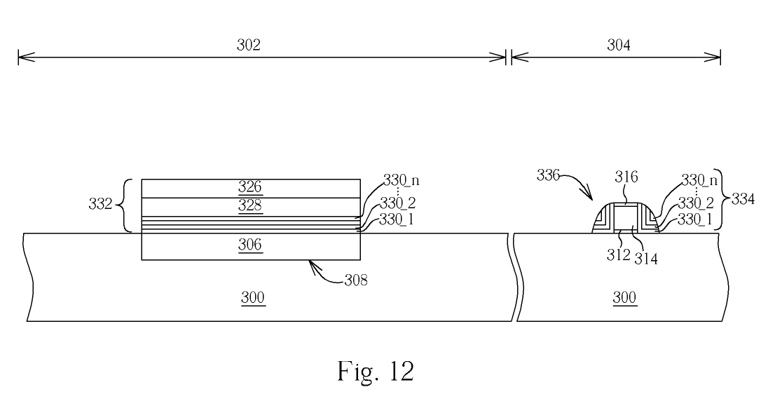

As shown in FIG. 12, at least an etching process is carried out to remove the multiple dielectric materials 318_1, 318_2 . . . 318_n not covered by the patterned mask 324. Therefore, a multiple dielectric layers 330_1, 330_2 . . . 330_n is formed on the photodiode 308 in the light sensor area 302, and at the same time, spacers 334 are formed on the sidewalls of the gate 310 in the device area 304. The patterned mask 324 is then removed. Accordingly, a stacked layer 332 comprising the multiple dielectric layers 330_1, 330_2 . . . 330_n, the first sacrifice layer 328, and the second sacrifice layer 326 is defined on the photodiode 308 in the light sensor area 302. Among the stacked layer 332, the multiple dielectric layers 330_1, 330_2 . . . 330_n acts as a selective film with the function of anti-reflection in an image sensor. It should be noticed that when the etching process is carried out to remove the multiple dielectric materials 318_1, 318_2 . . . 318_n on the photodiode 308 in the light sensor area 302, the etching process is also performed to etch back the multiple dielectric materials 318_1, 318_2 . . . 318_n in the device area 304. Thereby, the spacer 334 composed of the multiple dielectric layers 330_1, 330_2 . . . 330_n is formed on the sidewall of the gate 310 in the device area 304 and the gate structure 336 is consequently formed in the device area 304.

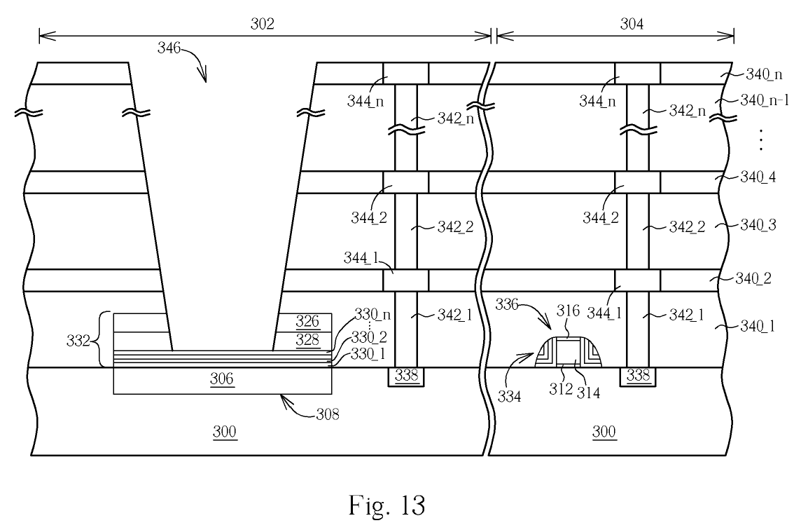

As shown in FIG. 13, corresponding dopants are implanted into the semiconductor substrate 300 to form light doped regions or source/drain regions, etc (not shown). Conductive regions 338 such as conductive dopant or metal silicide, etc, are formed within the semiconductor substrate 300. According to the different circuit designs, demanded inter-layer dielectric (ILD) layers 340_1, 340_2 . . . 340_n, conductive plugs 342_1, 342_2 . 342_n, and metal layers 344_1, 344_2 . 344_n are then formed on the semiconductor substrate 300. Among which the conductive regions 338 are connected with the corresponding metal layers 344_1 through the conductive plug 342_1; metal layers 344_1, 344_2 . . . 344_n are also connected with each other through the corresponding conductive plugs 342_2 . . . 342_n and therefore further connected to outside circuits or other devices.

Subsequently, a patterned mask (not shown) is coated on the semiconductor substrate 300 to define the predetermined position of forming a deep trench 346 on the photodiode 308 in the light sensor area 302. At least an etching process is carried out to remove the inter-layer dielectric layers 340_1, 340_2 . . . 340_n, the second sacrifice layer 326, and the first sacrifice layer 328 until the multiple dielectric layers 330_1, 330_2 . . . 330_n are exposed. Finally, the patterned mask is removed. The multiple dielectric layers 330_1, 330_2 . . . 330_n can be used as a selective film with the function of anti-reflection in an image sensor, and it can also be used as an etching stop layer in the aforesaid etching process for deep trench 346.

It should be noticed that the sacrifice layers (i.e. first sacrifice layer 328 and the second sacrifice layer 326) on the multiple dielectric layers 330_1, 330_2 . . . 330_n are not limited to the aforesaid double layers. Any single layer or multiple layers with an appropriate etching selectivity to the multiple dielectric layer s 330_1, 330_2 . . . 330_n, namely with the property of being removed completely and protecting the multiple dielectric layers 330_1, 330_2 . . . 330_n from damaging during the etching process of forming the deep trench 346, may be used as well.

Additionally, the number of layers and the materials used in the multiple dielectric layers 330_1, 330_2 . . . 330_n can be adjusted according to the acquired wavelength ranges and the strengths of the incident light received by the CMOS image sensors in order to increase the efficiency of photoelectric conversions. No matter what the multiple dielectric layers 330_1, 330_2 . . . 330_n are composed of, the spacer 334 in the device area 304 must be formed while the multiple dielectric layers 330_1, 330_2 . . . 330_n in the light sensor area 302 are formed. Therefore, the multiple dielectric layers 330_1, 330_2 . . . 330_n formed in the light sensor areas 302 and the spacers 334 formed in the device area 304 must comprise the same number of layers and the same constituent materials.

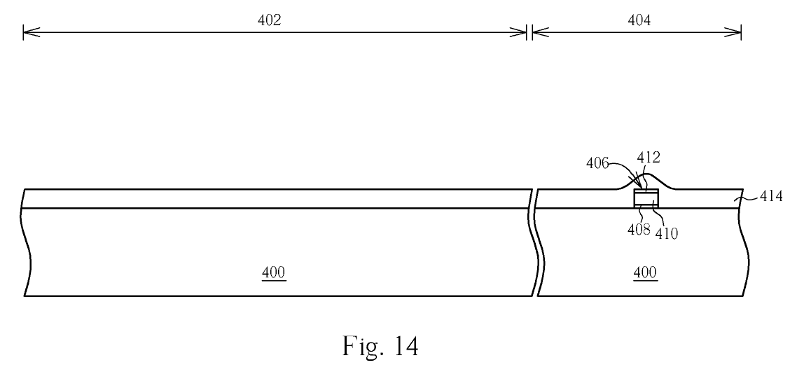

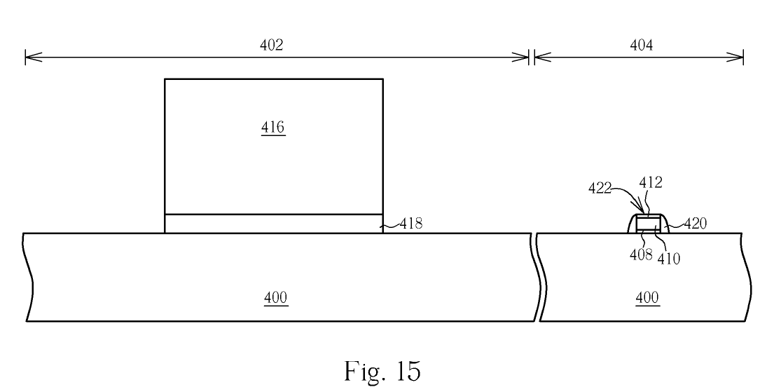

The method of simultaneously fabricating a selective film and a spacer according to the present invention is not limited to the CMOS image sensor fabrication process; the method may be used in any semiconductor fabrication process. Please refer to FIG. 14 to FIG. 15, which are cross-sectional diagrams illustrating a method of simultaneously fabricating a selective film and a spacer according to the third preferred embodiment of the present invention. For highlighting the characteristic of the present invention and for clarity of the illustration, FIG. 14 to FIG. 15 merely show a first device area and a second device area. As shown in FIG. 14, a semiconductor substrate 400 is provided such as a silicon substrate or a silicon-on-insulator (SOI) substrate, etc. The semiconductor substrate 400 comprises at least a first device area 402 and at least a second device area 404. The first device area 402 may further comprises at least a functional device (not shown) within the semiconductor substrate 400. A gate 406 is formed on the semiconductor substrate 400 in the second device area 404. The gate 406 comprises a gate dielectric layer 408, a gate conductive layer 410 positioned on the gate dielectric layer 408, and a cap layer 412 positioned on the gate conductive layer 410. Subsequently, at least a dielectric material 414 such as silicon oxide components, or silicon nitride components, etc, is formed on the semiconductor substrate 400. The dielectric material 414 covers the gate 406 in the second device area 404. The components and the number of layers of the dielectric materials 414 may be adjusted according to different designs of acquired semiconductor processes.

It should be noticed that the cap layer 412 is not limited to be formed on the gate conductive layer 410 at this time. It depends on the materials of the metal silicide, which is used to lower the sheet resistance, formed on the gate structure, source/drain region in the following fabrication processes. For example, if the metal silicide is composed of tungsten silicide, the cap layer 412 is formed on the gate conductive layer 410 at the time shown in FIG. 14. However, if the metal silicide is composed of cobalt silicide, or titanium silicide, or tantalum silicide, etc, formed by an self-aligned silicidation (salicide), then the cap layer 412 will not be formed on the gate conductive layer 410 at the time shown in FIG. 14. Those skilled in the art will readily observe that numerous modifications and alterations of the method may be made while retaining the teachings of the invention.

As shown in FIG. 15, a patterned mask 416 such as a photoresist is coated on the semiconductor substrate 400 to define a predetermined position of forming a patterned dielectric layer in the first device area 402. At least an etching process is then carried out to remove the dielectric material 414 not covered by the patterned mask 416 to form a patterned dielectric layer 418 in the first device area 404. While the etching process is performed, spacers 420 are simultaneously formed on the sidewalls of the gate 406 in the second device area 402; therefore a gate structure 422 is formed in the second device area 402. Finally, the patterned mask 416 is removed.

The patterned dielectric layer 418 and the spacer 420 formed as shown in FIG. 14 to FIG. 15 may be applied to any appropriate semiconductor processes such as a self-aligned silicidation (salicide) process. In a salicide process, the patterned dielectric layer 418 is used as a salicide barrier (SAB) to shield some portions of the semiconductor substrate 400 from forming the metal silicide. Accordingly, the acquired metal suicides are formed on the exposed portions of the semiconductor substrate 400 such as the semiconductor substrate 400 adjacent to the spacers 420, or the top portion of the gate 406.

One characteristic of the present invention is to form spacers on the sidewalls of a gate in the device area while a selective film is formed in the sensor area; therefore there is no need for additional deposition processed and etching processed to form the spacer as in the conventional processes. Besides, since the characteristic of the present invention is to simultaneously fabricate the selective film and the spacer, the problem of damaging the profile of the spacers as in the conventional process of defining the selective film will not occur. It should be noticed that the method of simultaneously fabricating a selective film and a spacer according to the present invention is not limited to the CMOS image sensor fabrication process; the method may be used in any semiconductor fabrication process.

Those skilled in the art will readily observe that numerous modifications and alterations of the device and method may be made while retaining the teachings of the invention.

What is claimed is:

1. A method for simultaneously fabricating a selective film and a spacer, comprising:
providing a semiconductor substrate, a first device area and a second device area with at least one gate defined on the semiconductor substrate;
forming at least a dielectric material on the semiconductor substrate, the dielectric material covering the first device area and the second device area;
forming a patterned mask to cover a portion of the dielectric material in the first device area;
performing an etching process to remove the dielectric material not covered by the patterned mask to form the selective film in the first device area and the spacers on sidewalls of the at least one gate in the second device area simultaneously; and
removing the patterned mask.

2. The method of claim 1, wherein the first device area comprises a sensor area.

3. The method of claim 2, further comprising at least a light sensor formed in the sensor area.

4. The method of claim 3, wherein the light sensor is a photodiode.

5. The method of claim 1, wherein each gate comprises:
a gate dielectric layer;
a gate conductive layer positioned on the gate dielectric layer; and
a cap layer positioned on the gate conductive layer.

6. The method of claim 1, further comprising a step of forming at least a sacrifice material on the dielectric material after forming the dielectric material, and the sacrifice material having a high etching selectivity in relative to the dielectric material.

7. The method of claim 6, further having an etching process that comprises removing the sacrifice material not covered by the patterned mask to form a sacrifice layer on the dielectric material.

8. The method of claim 7, wherein the method further comprises:
forming at least a conductive area within the semiconductor substrate;
forming at least an inter-layer dielectric (ILD) layer, at least a conductive plug, and at least a metal layer on the semiconductor substrate, and the inter-layer dielectric layer covering the selective film and the at least one gate with the spacers, and the metal layer connecting with the conductive area by the conductive plug; and
etching a portion of the inter-layer dielectric layer and a portion of the sacrifice layer until exposing the selective film to form a deep trench in the inter-layer dielectric layer above the selective film.

9. The method of claim 6, wherein the dielectric material comprises a silicon nitride material and the sacrifice material is composed of double layers comprising a silicon oxide material and a polysilicon material positioned on the silicon oxide material.

10. The method of claim 9, further having a etching process that comprises: performing an anisotropic dry etching to remove the polysilicon material of the sacrifice material not covered by the patterned mask to form a polysilicon layer on the silicon oxide material;
performing a wet etching to remove the silicon oxide material of the sacrifice material not covered by the patterned mask to form a silicon oxide layer on the silicon nitride material; and
performing an etching back process to remove the silicon nitride material not covered by the patterned mask to form the selective film.

11. The method of claim 1, wherein the selective film has the function of anti-reflection.

12. The method of claim 1, wherein the selective film is an etching stop layer.

13. An image sensor structure fabricated according to the method of claim 1, the image sensor structure comprising:
a semiconductor substrate, a first device area and a second device area defined on the semiconductor substrate;
at least a selective film positioned on the surface of the semiconductor substrate in the first device area; and
at least a gate structure with spacers positioned on the surface of the semiconductor substrate in the second device area, wherein the spacers of the gate structure and the selective film is made of same constituent material.

14. The image sensor structure of claim 13, wherein the first device area comprises a sensor area.

15. The image sensor structure of claim 14, further comprising at least a light sensor in the sensor area.

16. The image sensor structure of claim 15, wherein the light sensor is a photodiode.

17. The image sensor structure of claim 13, wherein the surface of the selective film further comprises at least a sacrifice layer, and the sacrifice layer has a high etching selectivity in relative to the selective film.

18. The image sensor structure of claim 13, wherein each of the at least one gate comprises:
a gate dielectric layer;
a gate conductive layer positioned on the gate dielectric layer;
a cap layer positioned on the gate conductive layer; and
the spacers positioned on sidewalls of the gate dielectric layer, the gate conductive layer, and the cap layer.

19. The image sensor structure of claim 13, wherein the selective film has the function of anti-reflection.

20. The image sensor structure of claim 13, wherein the selective film is an etching stop layer.
